(19) United States
(12) Patent Application Publication
(10) Pub. No.: US 2025/0232821 A1
(43) Pub. Date: Jul. 17, 2025

(54) THREE DIMENSIONAL MEMORY DEVICE

(71) Applicant: SAMSUNG ELECTRONICS CO., LTD., Suwon-si (KR)

(72) Inventors: Jaewoong KIM, Suwon-si (KR); Nam Wook KANG, Suwon-si (KR); Seung-Yeon LEE, Suwon-si (KR)

(73) Assignee: SAMSUNG ELECTRONICS CO., LTD., Suwon-si (KR)

(21) Appl. No.: 19/020,667

(22) Filed: Jan. 14, 2025

(30) Foreign Application Priority Data
Jan. 15, 2024 (KR) 10-2024-0005848

(51) Int. Cl. G11C 16/34

(52) U.S. Cl. CPC G11C 16/3418; G11C 16/3495

(57) ABSTRACT

A memory system includes a memory device including blocks, and a memory controller that controls the memory device. Each of the blocks includes plural sub blocks with different sizes. In a write operation on a selected block among the blocks, the memory controller selects one of the sub blocks included in the selected block as a start sub block, in which the write operation is first to be performed, based on status information about the sub blocks included in the selected block.

### CROSS-REFERENCE TO RELATED APPLICATION

This application claims priority under 35 U.S.C. § 119 to Korean Patent Application No. 10-2024-0005848 filed on Jan. 15, 2024, in the Korean Intellectual Property Office, the disclosures of which being incorporated by reference herein in its entirety.

### BACKGROUND

Embodiments of the present disclosure described herein relate to a memory system.

A memory device is used to store data and is classified as a volatile memory device or a nonvolatile memory device. As an example of the nonvolatile memory device, a flash memory device may be used in a mobile phone, a digital camera, a portable computer device, a stationary computer device, or any other device. As a data storage capacity necessary for an electronic device quickly increases, the capacity of the flash memory device is also quickly increasing.

Meanwhile, even though the flash memory device is a nonvolatile memory device, data stored in the flash memory device may be lost due to a program disturb, a read disturb, etc. Accordingly, it is advantageous to have a method of managing the flash memory device such that the disturb is minimized. In particular, as the capacity of the flash memory device greatly increases, the method of managing the flash memory device such that the disturb is minimized is even more advantageous.

### SUMMARY

It is an aspect to provide a memory system capable of minimizing a disturb.

According to an aspect of one or more embodiments, there is provided a memory system comprising a memory device including a plurality of blocks; and a memory controller configured to control the memory device. Each of the plurality of blocks includes a plurality of sub blocks with different sizes. In a write operation on a selected block among the plurality of blocks, the memory controller selects one of the plurality of sub blocks included in the selected block as a start sub block, in which the write operation is first to be performed, based on status information about the plurality of sub blocks included in the selected block.

According to an aspect of one or more embodiments, there is provided a memory system comprising a memory device including a plurality of blocks; and a memory controller configured to control the memory device. Each of the plurality of blocks includes a first sub block; a second sub block disposed adjacent to the first sub block; and a third sub block disposed adjacent to the second sub block. The memory controller includes a feature table including status information about the first sub block, the second sub block and the third sub block included in a selected block among the plurality of blocks; and a sub block selector configured to select one among the first sub block, the second sub block and the third sub block included in the selected block as a start sub block in which a write operation is first to be performed, based on the feature table.

According to an aspect of one or more embodiments, there is provided a operating method of a memory system which includes a plurality of blocks, the method comprising allocating a block, in which a write operation is to be performed, from among the plurality of blocks; selecting a start sub block, in which a write operation is first to be performed, from among a plurality of sub blocks included in the allocated block, based on status information of the plurality of sub blocks; and performing a write operation sequentially from the start sub block.

### BRIEF DESCRIPTION OF THE FIGURES

The above and other aspect will become apparent by describing in detail embodiments thereof with reference to the accompanying drawings.

FIG. 1 is a block diagram illustrating a memory system according to an embodiment.

FIG. 2 is a diagram illustrating a software architecture of a memory system of FIG. 1, according to an embodiment.

FIG. 3 is a diagram illustrating an example of a memory controller of FIG. 1, according to an embodiment.

FIG. 4 is a block diagram illustrating an example of a memory device of FIG. 1, according to an embodiment.

FIGS. 5A to 5D are diagrams illustrating an example of blocks included in a memory cell array of FIG. 4 and sub blocks included in each block, according to various embodiments.

FIG. 6 is a diagram illustrating an example of a feature table according to an embodiment.

FIG. 7 is a flowchart for describing a write operation according to an embodiment.

FIG. 8 is a flowchart illustrating an example of selecting a start sub block based on status information of sub blocks, according to an embodiment.

FIGS. 9 and 10 are diagrams for describing an embodiment, in which a start sub block is selected by using a random algorithm.

FIGS. 11A, 11B, 11C, and 12 are diagrams for describing an embodiment, in which a start sub block is selected by using a wrap-around algorithm.

FIGS. 13A, 13B, 14A, and 14B are diagrams for describing an embodiment, in which a start sub block is selected by using a wrap-around algorithm, in detail.

FIGS. 15 and 16 are diagrams for describing an embodiment, in which a start sub block is selected by using an erase count algorithm.

FIGS. 17 and 18 are diagrams for describing an embodiment, in which a start sub block is selected based on a penalty value.

### DETAILED DESCRIPTION

Below, various embodiments will be described in detail and clearly to such an extent that an ordinary one in the art easily carries out the various embodiments. In this specification, the phrase “at least one of A, B, or C” includes within its scope “only A”, “only B”, “only C”, “A and B”, “A and C”, “B and C”, and “A, B, and C.”

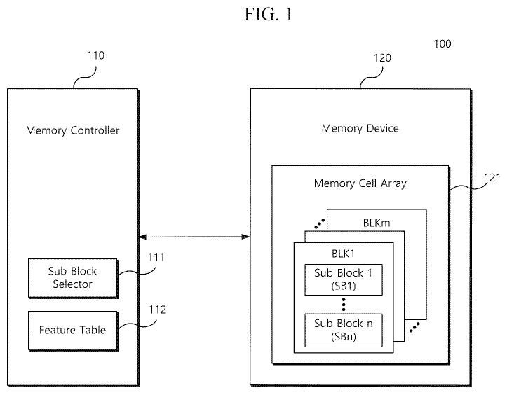

FIG. 1 is a block diagram illustrating a memory system 100 according to an embodiment.

The memory system 100 may include a plurality of blocks, and each of the plurality of blocks may include a plurality of sub blocks. In an embodiment, the plurality of sub blocks may have different sizes. When a write operation is performed, the memory system 100 may select a start sub block, in which the write operation is first to be performed, from among the plurality of sub blocks, based on status information about a plurality of sub blocks included in a block where the write operation is to be performed. Accordingly, a specific sub block may be prevented from being intensively used, and the disturb may be minimized.

The description will be given in detail with reference to FIG. 1. Referring to FIG. 1, the memory system 100 may include a memory controller 110 and a memory device 120.

The memory system 100 may be an internal storage device embedded in an electronic device. For example, in an embodiment, the memory system 100 may include an embedded universal flash storage (UFS) device or an embedded multi-media card (eMMC).

In some embodiments, the memory system 100 may be an external storage device removable from an electronic device. For example, in some embodiments, the memory system 100 may include a UFS memory card, a compact flash (CF) card, a secure digital (SD) card, a micro-SD card, a mini-SD card, an extreme digital (xD) card, or a memory stick.

However, this is provided as an example. According to some embodiments, the memory system 100 may be referred to as a “personal computer”, a “data center”, “network attached storage” (NAS), an “internet of things (IoT) device”, a “portable electronic device”, etc.

The memory controller 110 may control the memory device 120 depending on a request of an external device (e.g., a host). For example, the memory controller 110 may transmit an address and a command to the memory device 120 depending on the request of the external device. The memory controller 110 may exchange data with the memory device 120 depending on the request of the external device.

Under control of the memory controller 110, the memory device 120 may store data or may output the stored data. For example, in some embodiments, the memory device 120 may be implemented with a memory device including a NAND flash memory. However, this is provided as an example, and embodiments are not limited thereto. As another example, in some embodiments, the memory device 120 may be implemented with a memory device, which includes nonvolatile memory elements, such as a NOR flash memory, an MRAM, a PRAM, an ReRAM, or an FRAM. As another example, in some embodiments, the memory device 120 may be implemented with a memory device, which includes volatile memory elements, such as a DRAM.

The memory device 120 may include a memory cell array 121, and the memory cell array 121 may include a plurality of blocks BLK1 to BLKm. The value of m may be an integer. Each of the plurality of blocks BLK1 to BLKm may include a plurality of memory cells. Each of the plurality of memory cells may be a single level cell (SLC) storing one data bit or may be a multi-level cell (MLC) storing at least two data bits.

Each of the plurality of blocks BLK1 to BLKm may include a plurality of sub blocks SB1 to SBn. The value of n may be an integer. In an embodiment, a sub block may denote a minimum unit by which an erase operation is capable of being performed. For example, the memory device 120 may perform the erase operation in units of sub block. However, this is provided as an example. According to an embodiment, the memory device 120 may perform the erase operation in units of block.

In some embodiments, each of the plurality of blocks BLK1 to BLKm may have the same size. According to an embodiment, a super block including a plurality of blocks may be implemented. A block or a super block may be used, for example, as a data management unit of a normal I/O operation such as a write operation or a read operation.

In some embodiments, the plurality of sub blocks SB1 to SBn may have different sizes. For example, due to a characteristic of a physical structure of each block, the plurality of sub blocks SB1 to SBn may have different sizes. As another example, in the process of dynamically setting the plurality of sub blocks SB1 to SBn in each block, the plurality of sub blocks SB1 to SBn may be set to have different sizes. However, this is provided as an example. According to an embodiment, the plurality of sub blocks SB1 to SBn may be implemented to have the same size.

In an embodiment, the memory controller 110 may include a sub block selector 111 and a feature table 112. The feature table 112 may include status information about a plurality of sub blocks included in each block. The sub block selector 111 may select a start sub block, in which the write operation is first to be performed, from among a plurality of sub blocks, based on the status information of the plurality of sub blocks included in the feature table 112.

In detail, in an embodiment, when there is performed the write operation on a selected block, the sub block selector 111 may select the start sub block, based on size information about a plurality of sub blocks. For example, the sub blocks included in the selected block may have similar sizes. In this case, the sub block selector 111 may select the start sub block among the plurality of sub blocks by using a random algorithm to be described below.

In an embodiment, when there is performed the write operation on the selected block, the sub block selector 111 may select the start sub block, based on status information corresponding to the previously performed write operation. For example, the sub block selector 111 may refer to an I/O pattern of data previously stored in the selected block by the previous write operation and/or whether a block closing operation is performed after the previous write operation.

In an embodiment, the block closing operation may refer to an operation of changing a state of a block, in which data are present, to a free block state or making the block changeable to a free block state anytime. For example, the block closing operation may include an operation of copying valid data stored in a relevant block to any other block, an operation of erasing a sub block, in which invalid data are stored, from among sub blocks included in the relevant block, or an operation of storing dummy data in an empty space of a sub block, in which data are not stored.

When data are stored only in some of the plurality of sub blocks by the previous write operation and the block closing operation is performed, the sub block selector 111 may select the start sub block among the plurality of sub blocks by using a wrap-around algorithm to be described below.

In an embodiment, when there is performed the write operation on the selected block, the sub block selector 111 may select the start sub block, based on erase count information about the plurality of sub blocks. For example, erase counts of the sub blocks included in the selected block may be different from each other. In this case, the sub block selector 111 may select the start sub block among the plurality of sub blocks by using an erase count algorithm to be described below.

In an embodiment, when there is performed the write operation on the selected block, the sub block selector 111 may calculate a penalty value of the plurality of sub blocks and may again select the start sub block among the plurality of sub blocks based on the calculated penalty value.

As described above, the memory system 100 according to an embodiment may select the start sub block, in which the write operation is first to be performed, from among the plurality of sub blocks, based on the status information about the plurality of sub blocks. For example, the memory system 100 may select an optimal algorithm among various algorithms based on the status information about the plurality of sub blocks and may select the start sub block by using the selected optimal algorithm. Accordingly, a specific sub block may be prevented from being intensively used, and the disturb may be minimized.

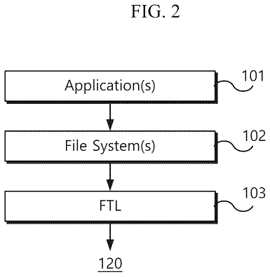

FIG. 2 is a diagram illustrating a software architecture of the memory system 100 of FIG. 1, according to an embodiment.

Referring to FIGS. 1 and 2, the software architecture of the memory system 100 may include an application 101, a file system 102, and a flash translation layer (FTL) 103. In an embodiment, the application 101 and the file system 102 may be included in an external device (e.g., a host) or may be driven by the external device.

The application 101 may include various programs which are driven on an operating system (OS) of the external device. For example, the application 101 may include various programs such as a text editor, an image player, and/or a web browser.

The file system 102 may perform a role of organizing files or data which are used by the application 101. For example, the file system 102 may provide an address of a file or data. In an embodiment, the address may be a logical address which is organized or managed by the external device.

The flash translation layer 103 provides an interface between the external device and the memory device 120 such that the memory device 120 is efficiently used. For example, the flash translation layer 103 may perform an operation of translating a logical address provided from the external device into a physical address usable in the memory device 120. For example, the flash translation layer 103 may manage the address translation operation through a mapping table.

In an embodiment, the sub block selector 111 (refer to FIG. 1) described above may be included in the flash translation layer 103. The flash translation layer 103 may control the memory device 120 such that a start sub block minimizing the disturb from among a plurality of sub blocks is selected.

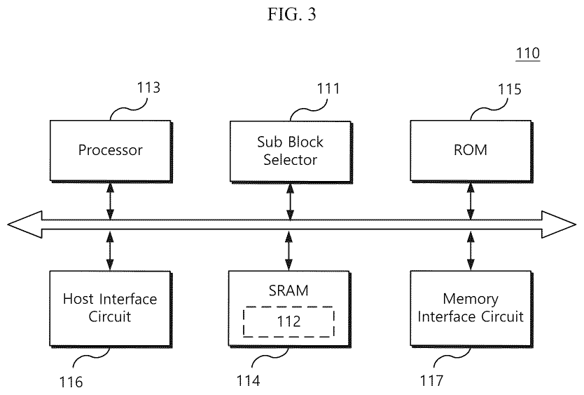

FIG. 3 is a diagram illustrating an example of the memory controller 110 of FIG. 1, according to an embodiment.

Referring to FIGS. 1 and 3, in an embodiment, the memory controller 110 may include the sub block selector 111, the feature table 112, a processor 113, an SRAM 114, a ROM 115, a host interface circuit 116, and a memory interface circuit 117.

The sub block selector 111 may select a start sub block, in which the write operation is first to be performed, from among a plurality of sub blocks, based on status information of the plurality of sub blocks. For example, the sub block selector 111 may select one algorithm among a random algorithm, a wrap-around algorithm, or an erase count algorithm based on the status information of the plurality of sub blocks and may select the start sub block by using the selected algorithm.

The feature table 112 may include status information about a plurality of sub blocks included in each plurality of blocks. For example, the feature table 112 may include information about the size of a sub block, information about a start sub block selected in a previous write operation, I/O pattern information about data stored in the previous write operation, and/or information about whether the block closing operation is performed after the previous write operation.

The processor 113 may control an overall operation of the memory controller 110. In an embodiment, the processor 113 may be processing circuitry configured to perform operations of the memory controller 110 described herein.

The SRAM 114 may be used as a buffer memory, a cache memory, or a working memory of the memory controller 110. However, this is provided as an example, and embodiments are not limited thereto. For example, according to an embodiment, the buffer memory, the cache memory, and the working memory may be provided independently of each other. According to an embodiment, as well as an SRAM, a volatile memory such as a DRAM or a nonvolatile memory may be used as the buffer memory, the cache memory, the working memory, etc.

The ROM 115 may store a variety of information, which is use for the memory controller 110 to operate, in the form of firmware.

The host interface circuit 116 may provide interfacing between the external device and the memory controller 110. For example, the host interface circuit 116 may be provided based on at least one of communication protocols such as universal serial bus (USB), multimedia card (MMC), eMMC (embedded MMC), peripheral component interconnection (PCI), PCI-express (PCI-E), advanced technology attachment (ATA), serial-ATA, parallel-ATA, small computer small interface (SCSI), enhanced small disk interface (ESDI), integrated drive electronics (IDE), Firewire, universal flash storage (UFS), non-volatile memory express (NVMe), and/or compute express link (CXL).

The memory interface circuit 117 may provide interfacing between the memory device 120 and the memory controller 110.

In an embodiment, the feature table 112 may be stored in the SRAM 114. In this case, the sub block selector 111 may select the start sub block among the plurality of sub blocks by referring to the feature table 112 stored in the SRAM 114.

In an embodiment, the sub block selector 111 may be a circuit implemented as processing circuitry independently of the processor 113. However, this is provided as an example. According to an embodiment, the sub block selector 111 may be implemented as a part of the processor 113. In some embodiments, the sub block selector 111 may be code stored in the SRAM 114 and may be read from the SRAM 114 and executed by the processor 113.

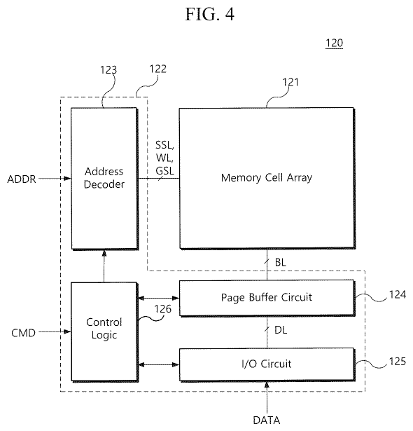

FIG. 4 is a block diagram illustrating an example of the memory device 120 of FIG. 1, according to an embodiment.

Referring to FIGS. 1 and 4, the memory device 120 may include the memory cell array 121 and a peripheral circuit 122, and the peripheral circuit 122 may include an address decoder 123, a page buffer circuit 124, an input/output (I/O) circuit 125, and control logic 126.

The memory cell array 121 may include a plurality of blocks. Each of the plurality of blocks may include a plurality of strings. Each of the plurality of strings may include a plurality of memory cells, and the plurality of memory cells in each string may be respectively connected to a plurality of word lines WL. Each of the plurality of blocks may include a plurality of sub blocks. According to an embodiment, the plurality of sub blocks may have different sizes. According to an embodiment, some of the plurality of sub blocks may have similar sizes.

The address decoder 123 may be connected to the memory cell array 121 through the word lines WL, string selection lines SSL, ground selection lines GSL. The address decoder 123 may receive an address ADDR from the memory controller 110 and may decode the received address ADDR. The address decoder 123 may select at least one of the plurality of word lines WL based on the decoded address ADDR.

The page buffer circuit 124 may be connected to the memory cell array 121 through a plurality of bit lines BL. The page buffer circuit 124 may be connected to the input/output circuit 125 through a plurality of data lines DL. The page buffer circuit 124 may control the plurality of bit lines BL such that data “DATA” received through the plurality of data lines DL are written in the memory cell array 121. The page buffer circuit 124 may read data stored in the memory cell array 121 by sensing voltage changes of the plurality of bit lines BL and may provide the read data to the input/output circuit 125 through the plurality of data lines DL.

The input/output (I/O) circuit 125 may exchange the data “DATA” with the memory controller 110.

The control logic 126 may receive a command CMD from the memory controller 110 and may control an overall operation of the memory device 120 in response to the received command CMD.

In an embodiment, when the write operation on the selected block is performed, the memory device 120 may receive information about a start sub block from the memory controller 110. In this case, the control logic 126 may control the memory device 120 such that the write operation is performed sequentially in a direction from the start sub block to a next adjacent sub block.

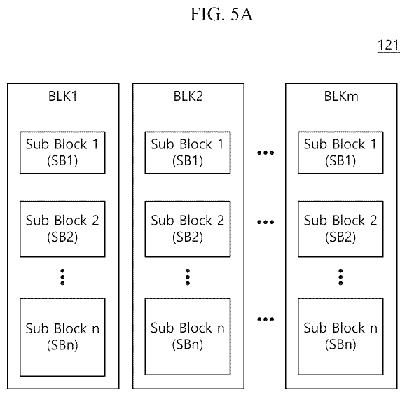

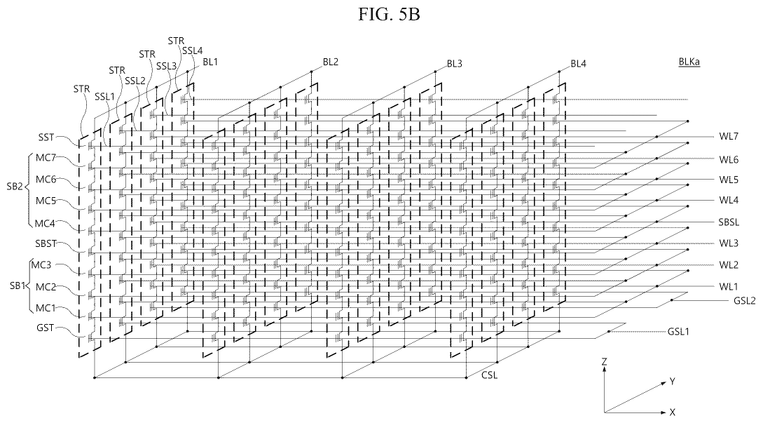

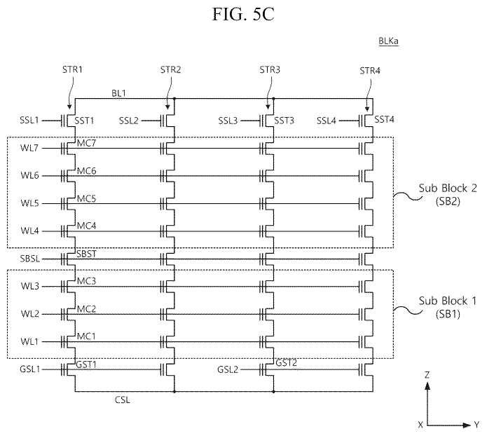

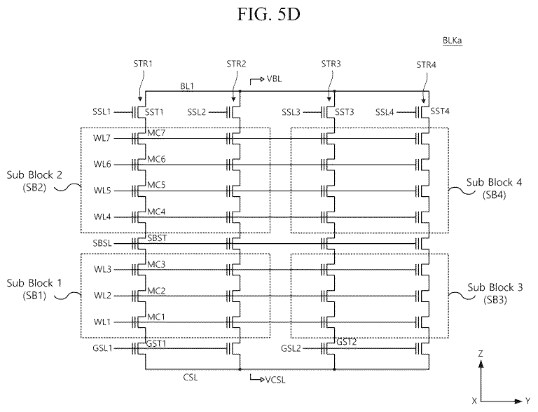

FIGS. 5A to 5D are diagrams illustrating an example of blocks included in the memory cell array 121 of FIG. 4 and sub blocks included in each block, according to various embodiments.

Referring to FIG. 5A, the memory cell array 121 may include the plurality of blocks BLK1 to BLKm. In an embodiment, the plurality of blocks BLK1 to BLKm may be implemented to have physically the same size.

Each of the plurality of blocks BLK1 to BLKm may include the plurality of sub blocks SB1 to SBn. According to an embodiment, the size of each of the plurality of sub blocks SB1 to SBn may be variously implemented or set.

In an embodiment, the plurality of sub blocks SB1 to SBn may have different sizes. For example, the first sub block SB1 and the second sub block SB2 may have implemented to have physically different sizes. As another example, the first sub block SB1 may be dynamically allocated to have a first size, and the second sub block SB2 may be dynamically allocated to have a second size different from the first size.

In an embodiment, some of the plurality of sub blocks SB1 to SBn may have different sizes, and the others thereof may have the same size. For example, the size of the first sub block SB1 may be the same as the size of the second sub block SB2 and may be different from the size of the third sub block (not illustrated).

In an embodiment, each of the plurality of sub blocks SB1 to SBn may have the same size.

An example of one block BLKa among the blocks BLK1 to BLKm of FIG. 4 is illustrated in FIG. 5B.

Referring to FIG. 5B, a plurality of strings STR may be arranged on a substrate in rows and columns. The plurality of strings STR may be connected in common to a common source line CSL formed on (or in) the substrate.

An example in which the common source line CSL is connected to lower ends of the strings STR is illustrated in FIG. 5B. However, it is sufficient if the common source line CSL is electrically connected to the lower ends of the strings STR, and embodiments are not limited to the case that the common source line CSL is physically located at the lower ends of the strings STR. An example is illustrated in FIG. 5B as the strings STR are arranged in a four-by-four matrix. However, the number of strings in the memory block BLKa may increase or decrease.

The strings STR in each row may be connected in common to a ground selection line GSL1 or GSL2. For example, the strings STR in first and second rows may be connected in common to the first ground selection line GSL1, and strings STR in third and fourth rows may be connected in common to the second ground selection line GSL2. However, this is provided as an example. For another example, four different ground selection lines may be provided, and the strings STR in the first to fourth rows may be implemented to be connected to the four different ground selection lines.

The strings STR in each row may be connected with a corresponding string selection line among first to fourth string selection lines SSL1 to SSL4. The strings STR in each column may be connected with a corresponding bit line among first to fourth bit lines BL1 to BL4.

Each string STR may include at least one ground selection transistor GST connected to the ground selection line GSL1 or GSL2, a plurality of memory cells MC1 to MC7 respectively connected to a plurality of word lines WL1 to WL7, and a string selection transistor SST connected to the string selection line SSL1, SSL2, SSL3, or SSL4. Also, each string STR may include a sub block separation transistor SBST connected to a sub block separation line SBSL.

In each string STR, the ground selection transistor GST, the memory cells MC1 to MC7, the sub block separation transistor SBST, and the string selection transistor SST may be connected in series along a direction perpendicular to the substrate and may be sequentially stacked along the direction perpendicular to the substrate.

The sub block separation transistors SBST according to an embodiment may be disposed at various locations.

In an embodiment, the sub block separation transistors SBST may be disposed at a location where the size of the first sub block SB1 is defined to be smaller than the size of the second sub block SB2.

For example, as illustrated in FIG. 5B, in each string STR, the sub block separation transistor SBST may be disposed between the third memory cell MC3 and the fourth memory cell MC4. In this case, in each string STR, the first to third memory cells MC1 to MC3 may be disposed below the sub block separation transistor SBST, and the fourth to seventh memory cells MC4 to MC7 may be disposed above the sub block separation transistor SBST. The first to third memory cells MC1 to MC3 disposed below the sub block separation transistors SBST may be referred to as a “first sub block SB1”, and the fourth to seventh memory cells MC4 to MC7 disposed above the sub block separation transistors SBST may be referred to as a “second sub block SB2”. The size of the first sub block SB1 may be smaller than the size of the second sub block SB2.

In an embodiment, the sub block separation transistors SBST may be disposed at a location where the size of the first sub block SB1 is defined to be larger than the size of the second sub block SB2.

For example, in each string STR, the sub block separation transistor SBST may be disposed between the fourth memory cell MC4 and the fifth memory cell MC5. In this case, the first to fourth memory cells MC1 to MC4 disposed below the sub block separation transistors SBST may be referred to as a “first sub block SB1”, and the fifth to seventh memory cells MC5 to MC7 disposed above the sub block separation transistors SBST may be referred to as a “second sub block SB2”.

Alternatively, in an embodiment, the sub block separation transistors SBST may be disposed at a location where the size of the first sub block SB1 is defined to be the same as the size of the second sub block SB2.

The sub block separation transistors SBST according to an embodiment may be allocated or formed in various schemes.

In an embodiment, at least one of a plurality of transistors included in the string STR formed on the substrate may be allocated to the sub block separation transistor SBST. In this case, the sub block separation transistor SBST may be dynamically allocated, and thus, the size of the first sub block SB1 and the size of the second sub block SB2 may be variously set depending on a usage mode.

In an embodiment, the sub block separation transistors SBST may be formed to be physically different from memory cells. For example, the sub block separation transistor SBST may be formed of an NMOS transistor, in which a charge storage layer is absent between a channel and a gate, unlike the memory cells.

In an embodiment, a channel structure constituting the string STR formed on the substrate may include a lower channel structure and an upper channel structure, and the lower channel structure and the upper channel structure may be formed by using different processes.

For example, when the memory device 120 is formed in a chip on peri (COP) structure, the diameter of the upper end of the lower channel structure may be larger than the diameter of the lower end of the upper channel structure. As another example, when the memory device 120 is formed in a chip to chip (C2C) structure, the diameter of the upper end of the lower channel structure may be smaller than the diameter of the lower end of the upper channel structure.

In the structure where the channel structure includes the lower channel structure and the upper channel structure, at least one of word lines located adjacent to the interface between the lower channel structure and the upper channel structure may be defined as a “sub block separation line SBSL”, and memory cells connected to the sub block separation line SBSL may be referred to as “sub block separation transistors SBST”.

In an embodiment, the sub block separation line SBSL may be formed at the upper end of the lower channel structure (or on an upper surface of the lower channel structure). For example, the ground selection lines GSL1 and GSL2, the first to third word lines WL1 to WL3, and the sub block separation line SBSL may correspond to the lower channel structure of each string STR, and the fourth to seventh word lines WL4 to WL7 and the string selection lines SSL1 to SSL4 may correspond to the upper channel structure of each string STR.

In an embodiment, the sub block separation line SBSL may be formed at the lower end of the upper channel structure (or on a lower surface of the upper channel structure). For example, the ground selection lines GSL1 and GSL2 and the first to third word lines WL1 to WL3 may correspond to the lower channel structure of each string STR, and the sub block separation line SBSL, the fourth to seventh word lines WL4 to WL7, and the string selection lines SSL1 to SSL4 may correspond to the upper channel structure of each string STR.

In an embodiment, a word line disposed on the upper surface of the lower channel structure may be set as a first sub channel selection line, and a word line disposed on the lower surface of the upper channel structure may be set as a second sub channel selection line.

In an embodiment, sub channels may be distinguished from each other in a way to bias a dummy word line, instead of setting a dedicated string selection transistor. For example, in the string STR including the lower channel structure and the upper channel structure, at least one of word lines disposed adjacent to the interface between the lower channel structure and the upper channel structure may be set as a dummy word line, and the first sub block SB1 and the second sub block SB2 may be distinguished from each other by biasing the dummy word line.

An example of the block BLKa in which the first sub block SB1 and the second sub block SB2 are capable of being distinguished from each other by the sub block separation line SBSL is illustrated in FIG. 5C. For convenience of description, first to fourth strings STR1 to STR4 connected to the first bit line BL1 are illustrated in FIG. 5C as an example. It is assumed that the sub block separation line SBSL is disposed between the third word line WL3 and the fourth word line WL4.

Referring to FIG. 5C, the block BLKa may include the first sub block SB1 and the second sub block SB2 and may perform the erase operation in units of sub block.

For example, in the erase operation on the first sub block SB1, an erase voltage (e.g., 22 V) may be provided through the common source line CSL, and a voltage (e.g., 16 V) lower than the erase voltage may be provided through the first and second ground selection lines GSL1 and GSL2. A ground voltage may be provided through the first bit line BL1, and the ground voltage may be provided through the first to fourth string selection lines SSL1 to SSL4. In this case, the sub block separation transistors SBST may be set to a non-conducting state. Accordingly, the erase operation on the first sub block SB1 may be performed.

As another example, in the erase operation on the second sub block SB2, the erase voltage (e.g., 22 V) may be provided through the first bit line BL1, and a voltage (e.g., 16 V) lower than the erase voltage may be provided through the first to fourth string selection lines SSL1 to SSL4. The ground voltage may be provided through the common source line CSL, and the ground voltage may be provided through the first and second ground selection lines GSL1 and GSL2. In this case, the sub block separation transistors SBST may be set to a non-conducting state. Accordingly, the erase operation on the second sub block SB2 may be performed.

As described above, the block BLKa may be divided into the first sub block SB1 and the second sub block SB2, and the erase operation may be performed in units of sub block.

As will be described below, according to an embodiment, when the write operation is performed, the write operation may be performed sequentially from a sub block selected as a start sub block from among the first sub block SB1 and the second sub block SB2.

An example of the block BLKa which is capable of being divided into first to fourth sub blocks SB1 to SB4 by the sub block separation line SBSL, the string selection lines SSL1 to SSL4, and the ground selection lines GSL1 and GSL2 is illustrated in FIG. 5D. For convenience of description, as in the above description given with reference to FIG. 5C, the first to fourth strings STR1 to STR4 connected to the first bit line BL1 are illustrated in FIG. 5D as an example. Also, it is assumed that the sub block separation line SBSL is disposed between the third word line WL3 and the fourth word line WL4.

Referring to FIG. 5D, the block BLKa may include the first to fourth sub blocks SB1 to SB4 and may perform the erase operation in units of sub block.

For example, in the erase operation on the first sub block SB1, the erase voltage (e.g., 22 V) may be provided through the common source line CSL, a voltage (e.g., 16 V) lower than the erase voltage may be provided through the first ground selection line GSL1, and the ground voltage may be provided through the second ground selection line GSL2. The ground voltage may be provided through the first bit line BL1, and the ground voltage may be provided through the first to fourth string selection lines SSL1 to SSL4. In this case, the sub block separation transistors SBST may be set to a non-conducting state. Accordingly, the erase operation on the first sub block SB1 may be performed.

As another example, in the erase operation on the second sub block SB2, the erase voltage (e.g., 22 V) may be provided through the first bit line BL1, a voltage (e.g., 16 V) lower than the erase voltage may be provided through the first and second string selection lines SSL1 and SSL2, and the ground voltage may be provided through the third and fourth string selection lines SSL3 and SSL4. The ground voltage may be provided through the common source line CSL, and the ground voltage may be provided through the first and second ground selection lines GSL1 and GSL2. In this case, the sub block separation transistors SBST may be set to a non-conducting state. Accordingly, the erase operation on the second sub block SB2 may be performed.

As another example, in the erase operation on the third sub block SB3, the erase voltage (e.g., 22 V) may be provided through the common source line CSL, a voltage (e.g., 16 V) lower than the erase voltage may be provided through the second ground selection line GSL2, and the ground voltage may be provided through the first ground selection line GSL1. The ground voltage may be provided through the first bit line BL1, and the ground voltage may be provided through the first to fourth string selection lines SSL1 to SSL4. In this case, the sub block separation transistors SBST may be set to a non-conducting state. Accordingly, the erase operation on the third sub block SB3 may be performed.

As another example, in the erase operation on the fourth sub block SB4, the erase voltage (e.g., 22 V) may be provided through the first bit line BL1, a voltage (e.g., 16 V) lower than the erase voltage may be provided through the third and fourth string selection lines SSL3 and SSL4, and the ground voltage may be provided through the first and second string selection lines SSL1 and SSL2. The ground voltage may be provided through the common source line CSL, and the ground voltage may be provided through the first and second ground selection lines GSL1 and GSL2. In this case, the sub block separation transistors SBST may be set to a non-conducting state. Accordingly, the erase operation on the fourth sub block SB4 may be performed.

As described above, the block BLKa may be divided into the first to fourth sub blocks SB1 to SB4, and the erase operation may be performed in units of sub block.

As will be described below, according to an embodiment, when the write operation is performed, the write operation may be performed sequentially from a sub block selected as a start sub block from among the first to fourth sub blocks SB1 to SB4.

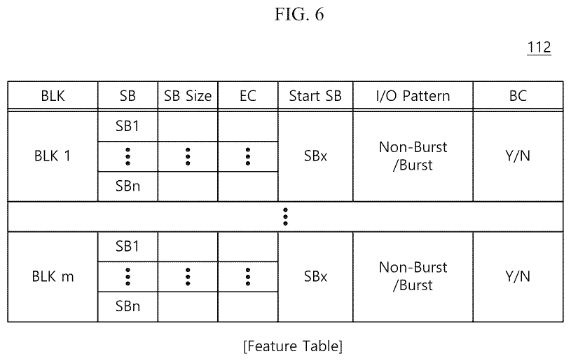

FIG. 6 is a diagram illustrating an example of a feature table according to an embodiment. For example, a feature table of FIG. 6 may correspond to the feature table 112 of FIG. 1.

Referring to FIG. 6, the feature table 112 may include status information about the plurality of sub blocks SB1 to SBn included in each of the plurality of blocks BLK1 to BLKm.

In an embodiment, the feature table 112 may include sub block size information SB Size for each of the plurality of sub blocks SB1 to SBn. The sub block selector 111 may determine whether to use the random algorithm among various algorithms for determining a start sub block based on the sub block size information SB Size and may execute the random algorithm based on a determination result.

In an embodiment, the feature table 112 may include information about a previous write operation, such as start sub block information Start SB, I/O pattern information I/O Pattern, and/or block closing information BC, for each of the plurality of blocks BLK1 to BLKm. In an embodiment, the I/O pattern information I/O Pattern may indicate whether data stored by the previous write operation are burst data or non-burst data. The block closing information BC may indicate whether the block closing operation on a relevant block in which data are stored in the previous write operation is performed after the data are stored in the relevant block. In an embodiment, the block closing information BC may indicate whether the block closing operation on the relevant block is repeatedly performed in a plurality of write operations previously performed.

The sub block selector 111 may determine whether to use the wrap-around algorithm among the algorithms for determining a start sub block based on the start sub block information Start SB, the I/O pattern information I/O Pattern, and the block closing information BC associated with the previous write operation and may execute the wrap-around algorithm based on a determination result.

In an embodiment, the feature table 112 may include erase count information EC for each of the plurality of sub blocks SB1 to SBn. The sub block selector 111 may execute the erase count algorithm among the algorithms for determining a start sub block based on the erase count information EC.

As described above, the feature table 112 may include status information about each block or status information about sub blocks included in each block, and the sub block selector 111 may select an optimal algorithm among various algorithms by referring to the feature table 112 and may select a start sub block by using the selected optimal algorithm.

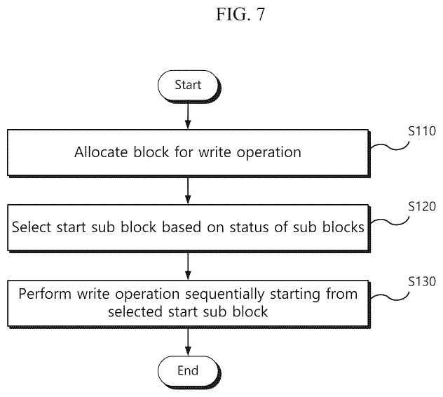

FIG. 7 is a flowchart for describing a write operation according to an embodiment.

In operation S110, a block for the write operation may be allocated.

For example, the memory controller 110 (refer to FIG. 1) may allocate one of a plurality of blocks of the memory cell array 121 for a block where data are to be stored.

In operation S120, a start sub block may be selected based on status information of sub blocks.

For example, the sub block selector 111 (refer to FIG. 1) of the memory controller 110 may select a start sub block where the write operation is first to be performed, based on status information of sub blocks included in the feature table 112 (refer to FIG. 1). In this case, the sub block selector 111 may select one among the random algorithm, the wrap-around algorithm or the erase algorithm based on the status information of the sub blocks and may select the start sub block by using the selected algorithm.

In operation S130, the write operation may be performed sequentially from the selected start sub block.

For example, the memory device 120 (refer to FIG. 1) may store data in the start sub block under control of the memory controller 110. In this case, write-requested data may be programmed sequentially from the start sub block to a next sub block.

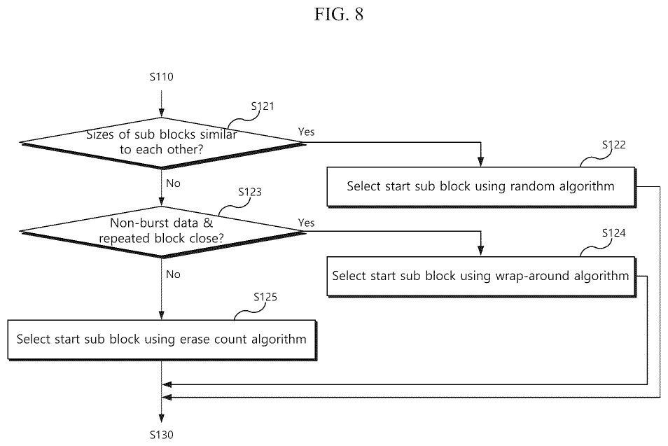

FIG. 8 is a flowchart illustrating an example of selecting a start sub block based on status information of sub blocks, according to an embodiment. For example, the operating method of FIG. 8 may correspond to operation S120 of FIG. 7.

Referring to FIG. 8, in operation S121, whether sub blocks have similar sizes may be determined. For example, the sub block selector 111 may determine whether sub blocks have similar sizes, based on sub block size information about sub blocks included in the feature table 112.

When it is determined that the sub blocks have similar sizes (S121, Yes), the random algorithm may be selected (S122). In this case, the sub block selector 111 may randomly select a start sub block among a plurality of sub blocks by using the random algorithm.

When it is determined that the sizes of the sub blocks are not similar to each other (S121, No), the procedure may proceed to operation S123.

In operation S123, whether data stored in sub blocks by a previous write operation are non-burst data and whether the block closing operation on a selected block is performed may be determined. For example, based on the I/O pattern information and the block closing information included in the feature table 112, the sub block selector 111 may determine whether the data stored in the sub blocks by the previous write operation are non-burst data and whether the block closing operation on the selected block is performed.

When it is determined that the data stored in the sub blocks by the previous write operation are non-burst data and the block closing operation on the selected block is performed (S123, Yes), the wrap-around algorithm may be selected (S124). In this case, the sub block selector 111 may select a start sub blocks by using the wrap-around algorithm. For example, when a first sub block is selected as a start sub block in the previous write operation, the sub block selector 111 may select a second sub block adjacent to the first sub block as a start sub block.

When it is determined that the data stored in the sub blocks by the previous write operation are burst data or the block closing operation on the selected block is not repeatedly performed (S123, No), the procedure may proceed to operation S125.

In operation S125, the erase count algorithm may be selected. The sub block selector 111 may select a sub block, in which the erase operation is smallest performed, as a start sub block by using the erase count algorithm.

As described above with reference to FIGS. 7 and 8, the operating method of the memory system according to an embodiment may select a start sub block, in which the write operation is first to be performed, from among a plurality of sub blocks based on status information about the plurality of sub blocks. Accordingly, a specific sub block may be prevented from being intensively used, and the disturb may be minimized.

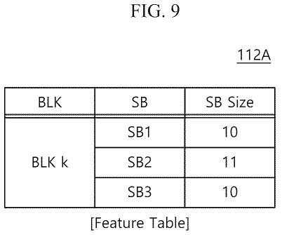

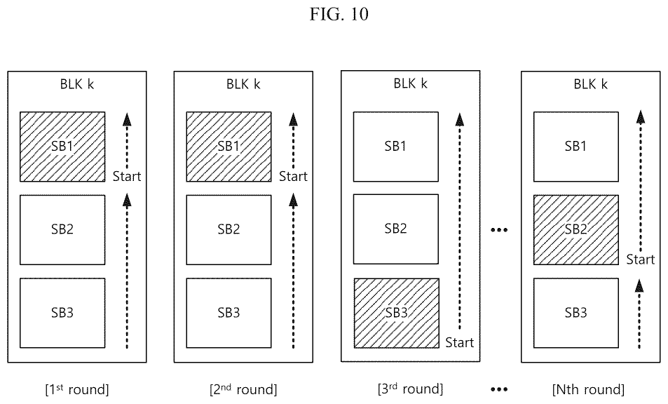

FIGS. 9 and 10 are diagrams for describing an embodiment, in which a start sub block is selected by using a random algorithm. In detail, a feature table including sub block size information is illustrated in FIG. 9 as an example. An example in which a start sub block is selected by using the random algorithm is illustrated in FIG. 10.

For convenience of description, it is assumed that a k-th block BLK k is identically allocated to store data in each round. Also, it is assumed that the k-th block BLK k includes the first to third sub blocks SB1 to SB3 and the first to third sub blocks SB1 to SB3 are disposed adjacent to each other. Also, it is assumed that when each round starts, the first to third sub blocks SB1 to SB3 included in the k-th block BLK k are free sub blocks where data are not stored.

Referring to FIG. 9, a feature table 112A may include the sub block size information SB Size of each of the first to third sub blocks SB1 to SB3 included in the k-th block BLK k. For example, as illustrated in FIG. 9, the first to third sub blocks SB1 to SB3 may have the same size or similar sizes. In this case, the sub block selector 111 may select a start sub block by using the random algorithm.

In detail, referring to FIG. 10, the sub block selector 111 may randomly select a start sub block in each round.

For example, in a first round, the k-th block BLK k may be allocated to store data. The sub block selector 111 may select the first sub block SB1 among the first to third sub blocks SB1 to SB3 of the k-th block BLK k as a start sub block by using the random algorithm. In this case, in the first round, the write operation may proceed sequentially in the order of “SB1-SB3-SB2”.

For example, in a second round, the sub block selector 111 may select the first sub block SB1 as a start sub block by using the random algorithm, and the write operation may proceed sequentially in the order of “SB1-SB3-SB2”.

For example, in a third round, the sub block selector 111 may select the third sub block SB3 as a start sub block by using the random algorithm, and the write operation may proceed sequentially in the order of “SB3-SB2-SB1”.

For example, in an N-th round, the sub block selector 111 may select the second sub block SB2 as a start sub block by using the random algorithm, and the write operation may proceed sequentially in the order of “SB2-SB1-SB3”.

When the first to third sub blocks SB1 to SB3 have the same size or similar sizes, as described above, a start sub block may be randomly selected in each round. In the case of a related art write operation, the order of the write operation in each round may be always the same as, for example, the order of “SB3-SB2-SB1”. In contrast, according to an embodiment, the start sub block may be randomly selected in each round by using the random algorithm. Accordingly, as the round is repeated, the first to third sub blocks SB1 to SB3 may be uniformly used. This uniform use may mean that a specific sub block is prevented from being intensively used, that is, the disturb is capable of being minimized.

The description is given with reference to FIGS. 9 and 10 under the assumption that when each round starts, the first to third sub blocks SB1 to SB3 included in the k-th block BLK k are free sub blocks. However, this is provided as an example, and it may be understood that embodiments are not limited thereto.

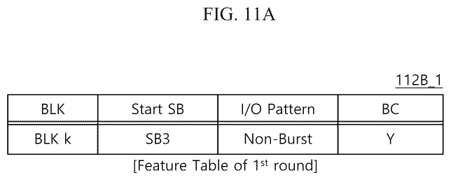

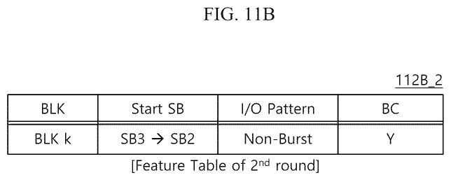

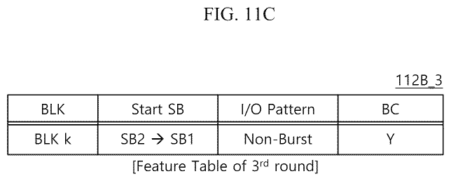

As another example, when each round starts, the first to third sub blocks SB1 to SB3 included in the k-th block BLK k may be in a state where data are stored therein. When invalid data are present in a sub block where data are to be stored, the erase operation on the sub block may be first performed before data are stored therein. When valid data are present in a sub block where data are to be stored, an operation of copying the data present in the sub block to any other block and an operation of erasing the sub block may be first performed. This configuration and operation may be identically applied to embodiments of FIGS. 11 to 18.

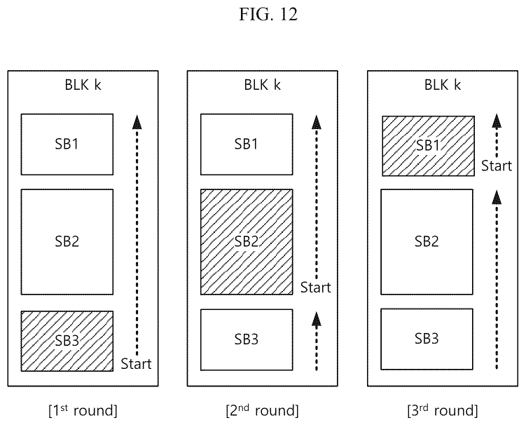

FIGS. 11A, 11B, 11C, and 12 are diagrams for describing an embodiment, in which a start sub block is selected by using a wrap-around algorithm. In detail, examples of feature tables respectively corresponding to first to third rounds are illustrated in FIGS. 11A to 11C. An example in which a start sub block is selected by using the wrap-around algorithm is illustrated in FIG. 12.

For convenience of description, as in the above description given with reference to FIGS. 9 and 10, it is assumed that the k-th block BLK k is allocated to store data in each round and the k-th block BLK k includes the first to third sub blocks SB1 to SB3. Also, it is assumed that, in each round, non-burst data are stored in the k-th block BLK k and the block closing operation is performed after the data write operation is performed.

Referring to FIGS. 11A and 12, in the first round, the k-th block BLK k may be allocated to store data. The third sub block SB3 may be selected as a start sub block. In this case, the write operation on the k-th block BLK k may proceed sequentially in the order of “SB3-SB2-SB1”.

The data stored in the k-th block BLK k in the first round may be non-burst data. For example, data may be stored only in the third sub block SB3 among the first to third sub blocks SB1 to SB3 included in the k-th block BLK k.

After the non-burst data are stored in the k-th block BLK k in the first round, there may be no input/output of additional data for a long time. For example, after the non-burst data are stored in the third sub block SB3, there may be no input/output of additional data for a long time. In this case, the block closing operation on the k-th block BLK k may be performed.

In detail, for example, when the block closing operation is performed, the valid data present in the third sub block SB3 of the k-th block BLK k may be copied to any other block. In this case, the third sub block SB3 may be in a state where only invalid data are stored. That is, the third sub block SB3 may be in a state of being changeable into a free sub block through the erase operation anytime.

As another example, when the block closing operation is performed, the valid data present in the third sub block SB3 of the k-th block BLK k may be copied to any other block, and the erase operation on the third sub block SB3 may then be performed. Accordingly, there may be a state where all the first to third sub blocks SB1 to SB3 are free sub blocks.

As another example, when the block closing operation is performed, the valid data present in the third sub block SB3 of the k-th block BLK k may be copied to any other block, and dummy data may be stored in an empty space of the third sub block SB3. Afterwards, the erase operation on the third sub block SB3 may be performed. Accordingly, there may be a state where all the first to third sub blocks SB1 to SB3 are free sub blocks.

As described above, in the first round, the third sub block SB3 is selected as a start sub block, non-burst data are stored in the k-th block BLK k, and the block closing operation on the k-th block BLK k is performed. In this case, status information about a block selected in the first round and the first to third sub blocks SB1 to SB3 included in the selected block may be updated in a feature table 112B_1, as illustrated in FIG. 11A, as the start sub block information Start SB, the I/O pattern information I/O Pattern, and the block closing information BC.

Referring to FIGS. 11B and 12, in the second round, the k-th block BLK k may be again allocated to store data. In this case, the sub block selector 111 (refer to FIG. 1) may refer to the feature table 112B_1 (refer to FIG. 11A) including the status information of the sub blocks associated with the first round.

In detail, the sub block selector 111 may check that the data I/O pattern are non-burst data and the block closing operation is performed, by referring to the feature table 112B_1 corresponding to the first round in which the previous write operation is performed. In this case, the sub block selector 111 may select a start sub block of the second round by using the wrap-around algorithm.

For example, as illustrated in FIG. 12, the sub block selector 111 may select, as a start sub block, a sub block adjacent to the start sub block selected in the first round. That is, the sub block selector 111 may select the second sub block SB2 adjacent to the third sub block SB3 as a start sub block.

Referring to FIGS. 11C and 12, in the third round, the k-th block BLK k may be again allocated to store data. In this case, the sub block selector 111 may refer to a feature table 112B_2 (refer to FIG. 11B) including the status information of the sub blocks associated with the second round.

In detail, the sub block selector 111 may check that the data I/O pattern are non-burst data and the block closing operation is performed, by referring to the feature table 112B_2 corresponding to the second round in which the previous write operation is performed. In this case, the sub block selector 111 may select a start sub block of the third round by using the wrap-around algorithm. For example, as illustrated in FIG. 12, the sub block selector 111 may select the first sub block SB1 adjacent to the second sub block SB2 as a start sub block.

As described above, when the block closing operation is performed in a state where data are stored only in some of a plurality of sub blocks in a previous write operation, a start sub block may be selected by using the wrap-around algorithm.

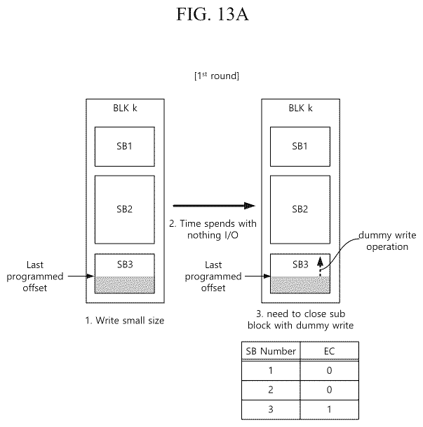

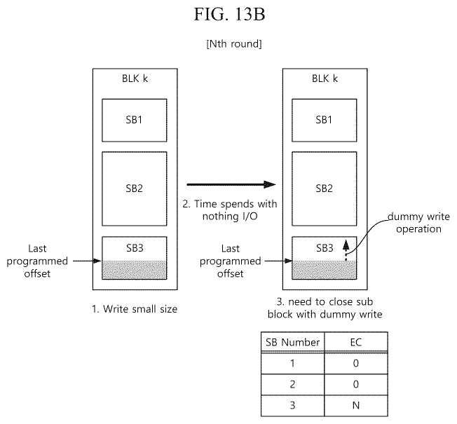

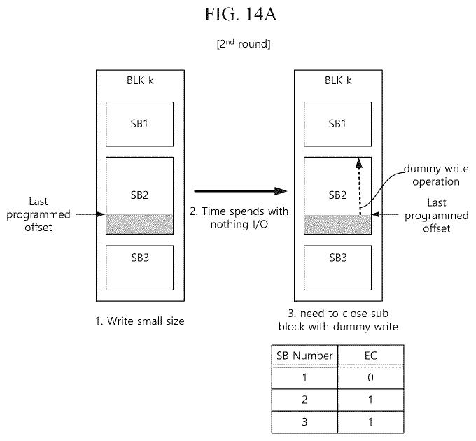

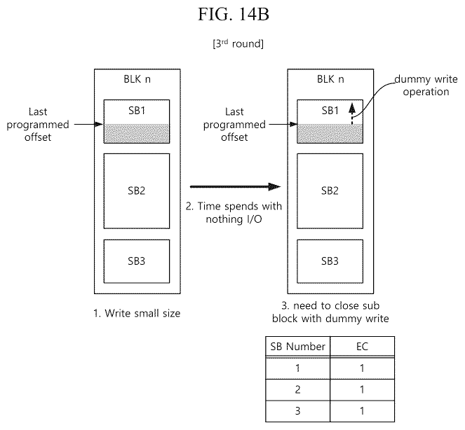

FIGS. 13A, 13B, 14A, and 14B are diagrams for describing an embodiment, in which a start sub block is selected by using a wrap-around algorithm, in detail. A related art write operation is illustrated in FIGS. 13A and 13B in detail. An example of the write operation using the wrap-around algorithm according to an embodiment is illustrated in FIGS. 14A and 14B.

For convenience of description, as in the above description given with reference to FIGS. 11 and 12, it is assumed that the k-th block BLK k is allocated to store data in each round and the k-th block BLK k includes the first to third sub blocks SB1 to SB3. Also, it is assumed that, in each round, non-burst data are stored in the k-th block BLK k and the dummy write operation and the block closing operation are performed.

First, referring to FIG. 13A, in the first round, data may be stored in a partial space of the third sub block SB3. Afterwards, there may be no input/output of additional data during a given time. In this case, the dummy write operation may be performed to store dummy data in an empty space of the third sub block SB3. Afterwards, the third sub block SB3 may be erased, and an erase count of the third sub block SB3 may increase as much as “1”.

In the case of a related art write operation, the write operation may proceed in the fixed order of “SB3-SB2-SB1”. Accordingly, when a situation in which non-burst data are stored in the third sub block SB3 in each round is repeated, the write operation, the dummy write operation, and the erase operation may be intensively performed in the third sub block SB3.

In this case, as illustrated in FIG. 13B, in the N-th round, the erase count EC of the third sub block SB3 may be “N”, and the erase count EC of each of the first and second sub blocks SB1 and SB2 may be “0”. To maintain the erase counts EC of the first to third sub blocks SB1 to SB3 mostly uniformly, wear leveling should be performed, that is, the erase operation on the first and second sub blocks SB1 and SB2 where data are not stored should be performed.

In contrast, a memory system according to an embodiment may use the first to third sub blocks SB1 to SB3 uniformly by using the wrap-around algorithm and may maintain the erase counts of the first to third sub blocks SB1 to SB3 uniformly.

For example, as illustrated in FIG. 14A, in the second round, the sub block selector 111 (refer to FIG. 1) may select the second sub block SB2 adjacent to the third sub block SB3, which corresponds to the start sub block of the first round, as a start sub block of the second round by using the wrap-around algorithm. In this case, data may be stored in a partial space of the second sub block SB2. Afterwards, when there is no input/output of additional data during a given time, dummy data may be stored in an empty space of the second sub block SB2, and the erase operation on the second sub block SB2 may then be performed. Accordingly, the erase count on the second sub block SB2 may increase as much as “1”.

As illustrated in FIG. 14B, in the third round, the sub block selector 111 may select the first sub block SB1 adjacent to the second sub block SB2 as a start sub block by using the wrap-around algorithm. In this case, data may be stored in a partial space of the first sub block SB1. Afterwards, when there is no input/output of additional data during a given time, dummy data may be stored in an empty space of the first sub block SB1, and the erase operation on the first sub block SB1 may then be performed. In this case, the erase count on the first sub block SB1 may increase as much as “1”.

As a result, when the wrap-around algorithm according to an embodiment is applied, the erase count EC of each sub block may be maintained to be the same as “1”, without performing an unnecessary erase operation. Accordingly, a specific sub block may be prevented from being intensively used or erased. This may mean that the disturb is minimized.

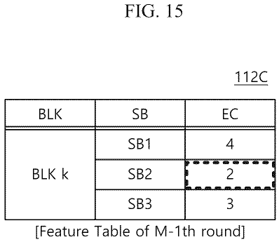

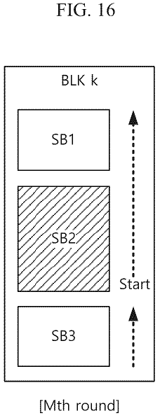

FIGS. 15 and 16 are diagrams for describing an embodiment, in which a start sub block is selected by using an erase count algorithm. An example of a feature table corresponding to an (M−1)-th round is illustrated in FIG. 15 in detail. An example in which a start sub block is selected by using the erase count algorithm in an M-th round is illustrated in FIG. 16.

For convenience of description, as in the above description given with reference to FIGS. 9 and 10, it is assumed that the k-th block BLK k is allocated to store data in each round and the k-th block BLK k includes the first to third sub blocks SB1 to SB3. Also, it is assumed that the erase count EC of the second sub block SB2 is the smallest in the (M−1)-th round.

Referring to FIG. 15, a feature table 112C may include the erase count information EC of each of the first to third sub blocks SB1 to SB3 included in the k-th block BLK k. For example, as illustrated in FIG. 15, in the (M−1)-th round, the erase count EC of the second sub block SB2 among the first to third sub blocks SB1 to SB3 may be the smallest.

In this case, as illustrated in FIG. 16, in the M-th round, the sub block selector 111 may select the second sub block SB2 with the smallest erase count as a start sub block. In this case, in the M-th round, the write operation may proceed sequentially in the order of “SB2 SB1-SB3”.

When data are only stored in the second sub block SB2 in the M-th round and then there is no input/output of additional data for a long time, the block closing operation on the k-th block BLK k may be performed. In this case, the data stored in the second sub block SB2 may be copied to any other block, and then, only the second sub block SB2 may be erased. As a result, as only the second sub block SB2 with the smallest erase count EC is erased, the number of times of the erase operation of each of the first to third sub blocks SB1 to SB3 may be uniformly maintained.

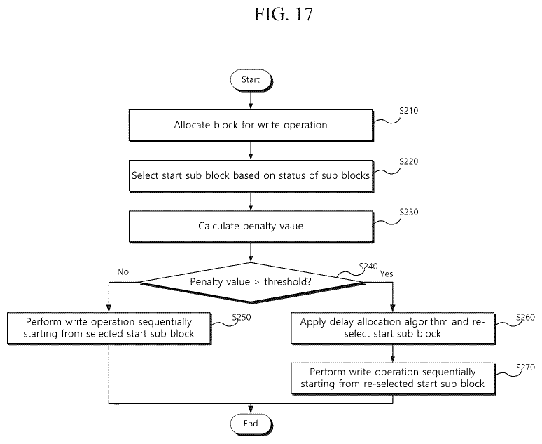

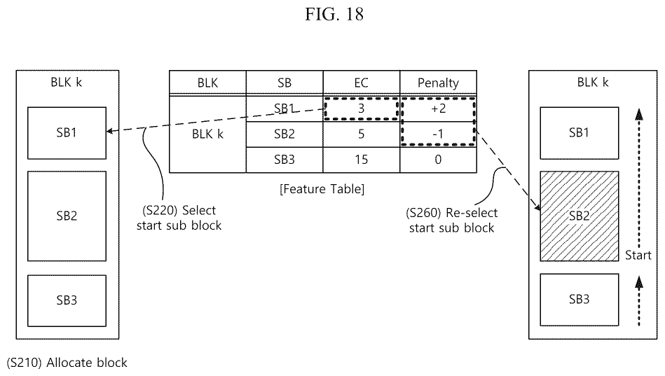

FIGS. 17 and 18 are diagrams for describing an embodiment, in which a start sub block is selected based on a penalty value. A flowchart according to an embodiment, in which a penalty value is applied, is illustrated in FIG. 17 in detail. An example in which a start sub block is re-selected based on a penalty value is illustrated in FIG. 18. The flowchart of FIG. 17 is similar to the flowcharts of FIGS. 7 and 8, and thus, additional description will be omitted to avoid redundancy.

Referring to FIG. 17, in operation S210, a block for the write operation may be allocated.

For example, as illustrated in FIG. 18, the k-th block BLK k may be allocated for the write operation.

In operation S220, a start sub block may be selected based on status information of sub blocks.

For example, as illustrated in FIG. 18, a start sub block may be selected by using the erase count algorithm. In this case, the sub block selector 111 (refer to FIG. 1) may check that the erase count of the first sub block SB1 is the smallest, by referring to a feature table, and may select the first sub block SB1 as a start sub block.

In operation S230, a penalty value may be calculated.

For example, as illustrated in FIG. 18, the erase count EC of the third sub block SB3 may be “15” and may be greater than the erase count EC of each of the first and second sub blocks SB1 and SB2.

In this case, to minimize the disturb, it may be advantageous to perform the erase operation on the second sub block SB2 adjacent to the third sub block SB3. Accordingly, the sub block selector 111 may set a negative value as a penalty value of the second sub block SB2 and may set a positive value as a penalty value of the first sub block SB1. For example, as illustrated in FIG. 18, the second sub block SB2 may have a penalty value of “−1”, and the first sub block SB1 may have a penalty value of “+2”.

In operation S240, whether a penalty value is greater than a threshold value may be determined.

When the penalty value is smaller than the threshold value (S240, No), operation S250 may be performed. In operation S250, the write operation may be performed sequentially from the start sub block selected in operation S220.

When the penalty value is greater than or equal to the threshold value (S240, Yes), operation S260 may be performed. In operation S260, a delay allocation algorithm may be applied, and a start sub block may be re-selected (i.e., a new sub block may be selected). Afterwards, in operation S270, the write operation may be performed sequentially from the re-selected start sub block (i.e., from the new sub block).

For example, referring to FIG. 18, the threshold value may be “+1”. In this case, because the penalty value of the first sub block SB1 is greater than the threshold value, the sub block selector 111 may not select the first sub block SB1 as a start sub block and may re-select the second sub block SB2 as a start sub block. Afterwards, the erase operation may be performed sequentially from the second sub block SB2.

According to the above description, a penalty value may be applied based on the status of each sub bock, and thus, the disturb may be minimized more effectively.

A memory system according to an embodiment may prevent a specific sub block from being intensively used by selecting a start sub block, in which a write operation is first to be performed, based on status information of sub blocks. Accordingly, the disturb may be minimized.

While various embodiments have been described with reference to the drawings, it will be apparent to those of ordinary skill in the art that various changes and modifications may be made thereto without departing from the spirit and scope of the present disclosure as set forth in the following claims.

What is claimed is:

1. A memory system comprising:
a memory device including a plurality of blocks; and
a memory controller configured to control the memory device,
wherein each of the plurality of blocks includes a plurality of sub blocks with different sizes,
wherein, in a write operation on a selected block among the plurality of blocks, the memory controller selects one of the plurality of sub blocks included in the selected block as a start sub block, in which the write operation is first to be performed, based on status information about the plurality of sub blocks included in the selected block.

2. The memory system of claim 1, wherein the memory controller selects the start sub block based on erase count information about the plurality of sub blocks included in the selected block.

3. The memory system of claim 2, wherein the memory controller selects a sub block, whose erase count is smallest, from among the plurality of sub blocks included in the selected block as the start sub block.

4. The memory system of claim 1, wherein the memory controller selects the start sub block based on I/O pattern information about data stored in the selected block and based on block closing information about the selected block.

5. The memory system of claim 4, wherein, when data stored in the selected block are non-burst data and a block closing for the selected block is performed in a previous round, the memory controller selects the start sub block by using a wrap-around algorithm.

6. The memory system of claim 1, wherein the memory controller selects the start sub block based on sub block size information about the plurality of sub blocks included in the selected block.

7. The memory system of claim 6, wherein, when sizes of the plurality of sub blocks included in the selected block are similar to each other, the memory controller selects the start sub block by using a random algorithm.

8. The memory system of claim 1, wherein the memory controller calculates a penalty value of the start sub block and when the penalty value is greater than a threshold value, the memory controller selects, as a new start sub block, one of remaining sub blocks among the plurality of sub blocks other than the start sub block.

9. The memory system of claim 1, wherein each of the plurality of blocks includes a plurality of memory cells vertically stacked on a substrate,
wherein a first sub block and a second sub block included in a first block are separated by a first sub block separation line disposed at a first height from the substrate, and
wherein a third sub block and a fourth sub block included in a second block are separated by a second sub block separation line disposed at a same height as the first sub block separation line.

10. The memory system of claim 9, wherein each of the first block and the second block includes a lower channel structure vertically formed on the substrate and an upper channel structure formed on the lower channel structure,
wherein the first sub block separation line is disposed on an interface between the lower channel structure and the upper channel structure of the first block, and
wherein the second sub block separation line is disposed on an interface between the lower channel structure and the upper channel structure of the second block.

11. A memory system comprising:
a memory device including a plurality of blocks; and
a memory controller configured to control the memory device,
wherein each of the plurality of blocks includes:
a first sub block;
a second sub block disposed adjacent to the first sub block;
a third sub block disposed adjacent to the second sub block, and
wherein the memory controller includes:
a feature table including status information about the first sub block, the second sub block and the third sub block included in a selected block among the plurality of blocks; and
a sub block selector configured to select one among the first sub block, the second sub block and the third sub block included in the selected block as a start sub block in which a write operation is first to be performed, based on the feature table.

12. The memory system of claim 11, wherein the status information includes erase count information about the first sub block, the second sub block and the third sub block included in the selected block, and
wherein the sub block selector selects a sub block, whose erase count is smallest, from among the first sub block, the second sub block and the third sub block included in the selected block as the start sub block.

13. The memory system of claim 11, wherein the status information includes I/O pattern information about data stored in the selected block, block closing information about the selected block, and information about the start sub block, and
wherein, when data stored in the selected block in a previous round are non-burst data and a block closing for the selected block is performed in the previous round, the sub block selector selects the start sub block by using a wrap-around algorithm.

14. The memory system of claim 11, wherein the status information includes sub block size information about the first sub block, the second sub block and the third sub block, and
wherein, when sizes of the first sub block, the second sub block and the third sub block are similar to each other, the sub block selector selects the start sub block by using a random algorithm.

15. The memory system of claim 11, wherein the sub block selector re-selects the start sub block, based on penalty values of the first sub block, the second sub block and the third sub block.

16. An operating method of a memory system which includes a plurality of blocks, the method comprising:
allocating a block, in which a write operation is to be performed, from among the plurality of blocks;
selecting a start sub block, in which a write operation is first to be performed, from among a plurality of sub blocks included in the allocated block, based on status information of the plurality of sub blocks; and
performing a write operation sequentially from the start sub block.

17. The method of claim 16, wherein selecting the start sub block includes:
determining whether sizes of the plurality of sub blocks are similar to each other; and
when the sizes of the plurality of sub blocks are similar to each other, selecting the start sub block by using a random algorithm.

18. The method of claim 16, wherein selecting the start sub block includes:
determining whether data stored in the allocated block in a previous write operation are non-burst data and whether a block closing operation on the allocated block is performed; and
when the data stored in the allocated block in the previous write operation are the non-burst data and the block closing operation on the allocated block is performed, selecting the start sub block by using a wrap-around algorithm.

19. The method of claim 16, wherein selecting the start sub block includes:
selecting a sub block, whose erase count is smallest, from among the plurality of sub blocks as the start sub block.

20. The method of claim 16, further comprising:
calculating a penalty value of the start sub block; and
when the penalty value is greater than a threshold value, selecting, as a new start sub block, one of remaining sub blocks among the plurality of sub blocks other than the start sub block.
